(19) United States
(12) Patent Application Publication
(10) Pub. No.: US 2007/0186857 A1
(43) Pub. Date: Aug. 16, 2007

(54) Plasma processing apparatus and method of using the same

(75) Inventors: Ju-Youn Kim, Suwon-si (KR); Seok-Jun Won, Seoul (KR); Weon-Hong Kim, Suwon-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/700,785

(22) Filed: Feb. 1, 2007

(30) Foreign Application Priority Data
Feb. 13, 2006 (KR) 10-2006-0013904

(51) Int. Cl. B08B 6/00; C23C 16/00

(52) U.S. Cl. 118/723 R; 134/1.1

(57) ABSTRACT

Example embodiments relate to an apparatus and method for manufacturing a semiconductor device. Other example embodiments relate to a plasma processing apparatus having an in-situ cleaning function and a method of using the same. The plasma processing apparatus may include an outer chamber, an inner chamber installed in the outer chamber, a gas supply unit for supplying a process gas or a cleaning gas into the inner chamber, an electrode positioned in the inner chamber, an electrode plasma power supply for applying power to the electrode, a first flexible member connecting the inner chamber and the outer chamber and having a first connector therein electrically connected to the inner chamber and/or a first chamber plasma power supply connected to the first connector and applying power to the inner chamber through the first connector.

### PRIORITY STATEMENT

This application claims the benefit of priority under 35 U.S.C. §119 from Korean Patent Application No. 2006-13904, filed Feb. 13, 2006 in the Korean Intellectual Property Office, the contents of which are hereby incorporated herein by reference in their entirety.

### BACKGROUND OF THE INVENTION

1. Field of the Invention

Example embodiments relate to an apparatus and method for manufacturing a semiconductor device. Other example embodiments relate to a plasma processing apparatus having an in-situ cleaning function and a method of using the same.

2. Description of Related Art

A semiconductor device manufacturing process may include a process of forming a thin layer on a substrate (e.g., a wafer). Methods of forming a thin layer on a substrate may include a physical vapor deposition (PVD) method, a chemical vapor deposition (CVD) method and an atomic layer deposition (ALD) method. The PVD method may be not be ideal for achieving both an increased step coverage and a smoother continuous layer when a step is formed on the surface of the substrate. The CVD method may have limitations (e.g., problems related to forming a thin layer at a relatively higher temperature and controlling thickness to an accuracy of several Å).

The conventional art acknowledges that the ALD method may be widely used to form a thin layer. The ALD method may include a method of depositing a thin layer on a substrate to a desired thickness by continuously repeating a process of sequentially supplying various source gases into a reaction chamber in desired time intervals. The ALD method may be capable of providing increased step coverage and more accurately controlling thickness. The ALD method may take a longer amount of time because the deposition cycle may be continuously repeated until the thin layer reaches the desired thickness.

A plasma enhanced atomic layer deposition (PEALD) method, which demonstrates an increased deposition speed of a thin layer by generating plasma in a reactor before supplying a secondary reaction gas into the reactor, has also been acknowledged by the conventional art.

If the processes are continuously performed using the above-described methods of forming a thin layer, then thin layers may accumulate on an interior of the reactor. The accumulated layers may function as an impurity, or a particle source having an adverse affect, on the thin layer deposited on the substrate. In conventional equipment used to form a thin layer, processes may be performed for a desired amount of time or a desired number of times. The reactor and other components in the equipment may be disassembled and cleaned using a wet cleaning method. If a wet cleaning method is used, then more time may be necessary for disassembly, assembly and/or arrangement of the equipment in addition to the time need for actual cleaning.

### SUMMARY OF THE INVENTION

Example embodiments relate to an apparatus and method for manufacturing a semiconductor device. Other example embodiments relate to a plasma processing apparatus having an in-situ cleaning function and a method of using the same.

A plasma processing apparatus in accordance with example embodiments disclosed herein include an outer chamber, an inner chamber installed in the outer chamber, a gas supply unit for supplying a process gas or a cleaning gas into the inner chamber, an electrode positioned in the inner chamber, an electrode plasma power supply for applying power to the electrode, a first connecting member connecting the inner chamber and the outer chamber and having a first connector therein electrically connected to the inner chamber and/or a first chamber plasma power supply connected to the first connector and applying power to the inner chamber through the first connector. The first connecting member may be a first flexible member.

In other example embodiments, the first chamber plasma power supply may include at least two plasma power supplies for applying power of different frequencies into the inner chamber.

In other example embodiments, the inner chamber may include a susceptor for mounting a substrate and/or a cover positioned on the susceptor to define a space for performing a process. The first flexible member may connect the cover and the outer chamber. The first chamber plasma power supply may apply power to the cover through the first connector. In other example embodiments, the first flexible member may connect the susceptor and the outer chamber. The first chamber plasma power supply may apply power to the susceptor through the first connector.

In still other example embodiments, the plasma processing apparatus may further include a second flexible member connecting the cover and the outer chamber and having a second connector therein electrically connected to the cover and/or a second chamber plasma power supply connected to the second connector and applying power to the cover through the second connector. The second chamber plasma power supply may include at least two plasma power supplies for applying power of different frequencies into the cover.

In yet other example embodiments, a non-conductive material layer may be coated on an outer surface of the inner chamber. The non-conductive material may be formed of ceramic.

A plasma processing apparatus in accordance with example embodiments disclosed herein may include an outer chamber, an inner chamber installed in the outer chamber and having a susceptor for mounting a substrate and a cover disposed (or positioned) on the susceptor to define a space for performing a process, a gas supply unit for supplying a process gas or a cleaning gas into the inner chamber, an electrode disposed (or positioned) in the inner chamber, an electrode plasma power supply for applying power to the electrode, a first connecting member connecting the cover and the outer chamber and having a connector therein electrically connected to the cover and/or a chamber plasma power supply connected to the connector and applying power to the cover through the connector. The first connecting member may be a fixing member.

In example embodiments, the chamber plasma power supply may include at least two plasma power supplies for applying power of different frequencies to the cover.

In other exemplary embodiments, a non-conductive material layer may be coated on an outer surface of the inner chamber. The non-conductive layer may be formed of ceramic.

A method of using a plasma processing apparatus in accordance with other example embodiments disclosed herein may include supplying a process gas into an inner chamber installed in an outer chamber to perform a thin-layer forming process on a substrate mounted therein, supplying a cleaning gas into the inner chamber, applying separate powers to the inner chamber and an electrode disposed (or positioned) in the inner chamber and cleaning the inner chamber using plasma generated from the cleaning gas and/or supplying a low discharge gas having a discharge rate lower than argon gas between the outer chamber and the inner chamber.

In yet other example embodiments, the method may further include, exchanging the substrate, on which the thin-layer forming process is performed, with a dummy wafer before supplying the cleaning gas into the inner chamber.

In other example embodiments, the lower discharge gas may include O₂ gas, N₂ gas or a mixed gas thereof.

In still other example embodiments, the method may further include connecting a flexible member between the inner chamber and the outer chamber before applying power to the inner chamber and/or interposing a connector electrically connected to the inner chamber in the flexible member. The power may be supplied to the inner chamber through the connector. The method may further include maintaining an internal pressure of the flexible member at a vacuum level before applying the power to the inner chamber.

A method of using a plasma processing apparatus in accordance with example embodiments disclosed herein may include supplying a process gas into an inner chamber installed in an outer chamber to perform a thin-layer forming process on a substrate mounted therein, supplying a cleaning gas into the inner chamber, applying separate powers to the inner chamber and an electrode disposed (or positioned) in the inner chamber and cleaning the inner chamber using plasma generated from the cleaning gas and/or maintaining a pressure between the outer chamber and the inner chamber at a desired vacuum level sufficient to suppress generation of the plasma.

In other example embodiments, the method may further include, exchanging the substrate, on which the thin-layer forming process is performed, with a dummy wafer before supplying the cleaning gas into the inner chamber.

In other example embodiments, the desired vacuum level may be above 10 Torr or below 10 mTorr.

In still other example embodiments, the method may further include connecting a flexible member between the inner chamber and the outer chamber before applying the power to the inner chamber and/or interposing (or positioned between) a connector electrically connected to the inner chamber in the flexible member. The power may be supplied to the inner chamber through the connector. The method may further include maintaining an internal pressure of the flexible member at a vacuum level before applying the power to the inner chamber.

### BRIEF DESCRIPTION OF THE DRAWINGS

Example embodiments will be more clearly understood from the following detailed description taken in conjunction with the accompanying drawings. FIGS. 1-6 represent non-limiting, example embodiments as described herein.

FIGS. 1-4 are diagrams illustrating schematic view of a plasma processing apparatus according to example embodiments.

FIGS. 5-6 are flowcharts of methods of using a plasma processing apparatus according to example embodiments.

### DETAILED DESCRIPTION OF THE EXAMPLE EMBODIMENTS

Various example embodiments will now be described more fully with reference to the accompanying drawings in which some example embodiments are shown. In the drawings, the thicknesses of layers and regions may be exaggerated for clarity.

Detailed illustrative embodiments are disclosed herein. However, specific structural and functional details disclosed herein are merely representative for purposes of describing example embodiments. This invention may, however, may be embodied in many alternate forms and should not be construed as limited to only the example embodiments set forth herein.

Accordingly, while the example embodiments are capable of various modifications and alternative forms, embodiments thereof are shown by way of example in the drawings and will herein be described in detail. It should be understood, however, that there is no intent to limit the example embodiments to the particular forms disclosed, but on the contrary, example embodiments are to cover all modifications, equivalents, and alternatives falling within the scope of the invention. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the example embodiments. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments only and is not intended to be limiting of the example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the scope of the example embodiments.

Spatially relative terms, such as “beneath,” “below,” “lower,” “above,” “upper” and the like, may be used herein for ease of description to describe one element or a relationship between a feature and another element or feature as illustrated in the figures. It will be understood that the spatially relative terms are intended to encompass different orientations of the device in use or operation in addition to the orientation depicted in the Figures. For example, if the device in the figures is turned over, elements described as “below” or “beneath” other elements or features would then be oriented “above” the other elements or features. Thus, for example, the term “below” can encompass both an orientation which is above as well as below. The device may be otherwise oriented (rotated 90 degrees or viewed or referenced at other orientations) and the spatially relative descriptors used herein should be interpreted accordingly.

Example embodiments are described herein with reference to cross-sectional illustrations that are schematic illustrations of idealized embodiments (and intermediate structures). As such, variations from the shapes of the illustrations as a result, for example, of manufacturing techniques and/or tolerances, may be expected. Thus, example embodiments of the invention should not be construed as limited to the particular shapes of regions illustrated herein but may include deviations in shapes that result, for example, from manufacturing. For example, an implanted region illustrated as a rectangle may have rounded or curved features and/or a gradient (e.g., of implant concentration) at its edges rather than an abrupt change from an implanted region to a non-implanted region. Likewise, a buried region formed by implantation may result in some implantation in the region between the buried region and the surface through which the implantation may take place. Thus, the regions illustrated in the figures are schematic in nature and their shapes do not necessarily illustrate the actual shape of a region of a device and do not limit the scope.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In order to more specifically describe example embodiments, various aspects will be described in detail with reference to the attached drawings. However, the present invention is not limited to the example embodiments described.

Example embodiments relate to an apparatus and method for manufacturing a semiconductor device. Other example embodiments relate to a plasma processing apparatus having an in-situ cleaning function and a method of using the same.

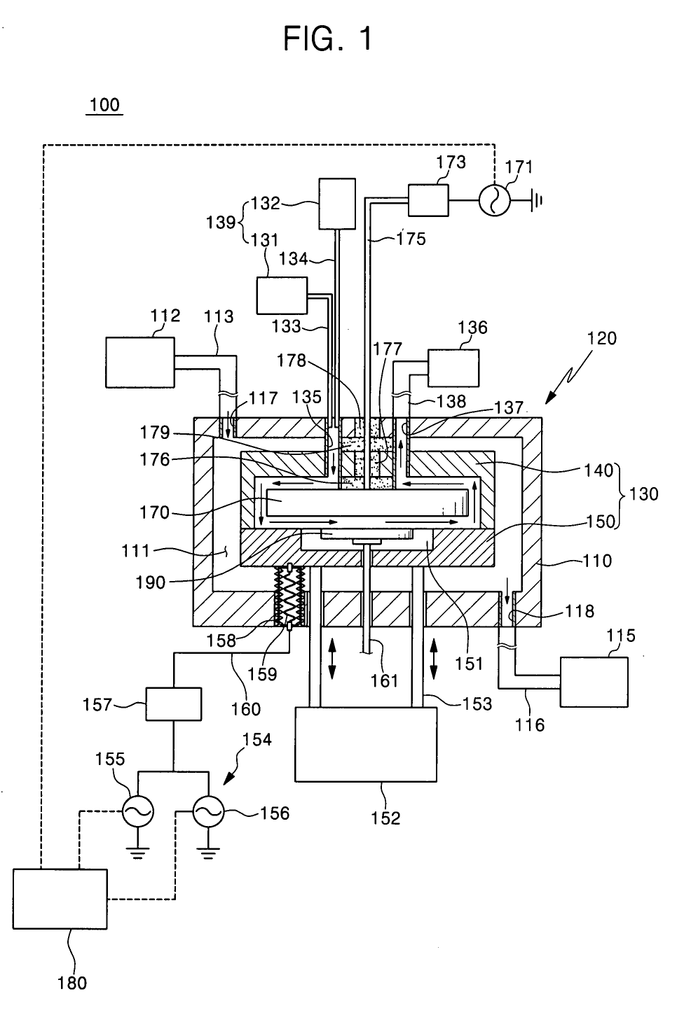

FIG. 1 is a diagram illustrating a schematic view of a plasma processing apparatus according to example embodiments.

Referring to FIG. 1, the plasma processing apparatus 100 according to example embodiments herein may include a reaction chamber 120 for performing a formation process. The reaction chamber 120 may perform a CVD process, an ALD process, a PEALD process or the like in order to form a thin layer on a substrate. Hereinafter, the operation of the reaction chamber 120 using the PEALD method will be described. The reaction chamber 120 may perform an in-situ cleaning function therein.

The reaction chamber 120 may include an outer chamber 110 having a closed space of a desired size and/or an inner chamber 130 installed in the outer chamber 110 and having a reaction space of a desired size. The inner chamber 130 may be spaced apart from an inner surface of the outer chamber 110 by a desired distance, forming an interspace 111. The interspace 111 may be formed between an outer surface of the inner chamber 130 and an inner surface of the outer chamber 110. Reference numeral 179 denotes an insulating member for insulating between the inner chamber 130 and the outer chamber 110.

The outer chamber 110, which may be formed of a conductive material (e.g., metal), may be grounded. A gas supply port 117 may be formed at one side of the outer chamber 110 to supply a gas into the outer chamber 110. A gas supply unit 112 may be connected to the gas supply port 117. The gas supply unit 112 may supply a gas into the outer chamber 110 through a gas supply line 113 connecting the gas supply unit 112 and the gas supply port 117 in order to adjust an internal pressure of the outer chamber 110 to a desired pressure appropriate to the process or maintain the internal pressure. The gas supply unit 112 may continuously, or selectively, supply a gas into the outer chamber 110 depending on needs. The gas supply unit 112 may supply the gas using a central control unit 180 that controls the plasma processing apparatus 100.

The gas supply unit 112 may supply a low discharge gas having a discharge rate lower than argon gas into the outer chamber 110. The gas supply unit 112 may supply low discharge gases (e.g., O₂ gas, N₂ gas, Ar/O₂ gas, Ar/N₂ gas, etc.) into the outer chamber 110. Because the low discharge gases may be present in the outer chamber 110 (i.e., between the outer chamber 110 and the inner chamber 130), a rate at which the plasma is generated in the outer chamber 110 and the inner chamber 130 may decrease in comparison to when argon gas is present between the outer chamber 110 and the inner chamber 130.

A gas exhaust port 118 may be formed at the other side of the outer chamber 110 to exhaust the gas in the outer chamber 110. A gas exhaust unit 115 may be connected to the gas exhaust port 118. The gas exhaust unit 115 may exhaust the gas in the outer chamber 110 to the exterior through a gas exhaust line 116 connecting the gas exhaust unit 115 and the gas exhaust port 118. The internal pressure in the outer chamber 110 may be adjusted by operation of the gas supply unit 112 and the gas exhaust unit 115.

The inner chamber 130 may include a susceptor 150 for supporting a wafer 190 and/or a cover 140 disposed (or positioned) on the susceptor 150 to define a space for performing the formation process. The susceptor 150 and the cover 140 may contact each other in order to provide space for performing the formation process. A gap between the susceptor 150 and the cover 140 may be sealed by forming a direct contact between a surface of the susceptor 150 and a surface of the cover 140. The susceptor 150 and the cover 140 may be separated from each other when the wafer 190 is loaded or unloaded. The inner chamber 130 may be formed of a conductive material (e.g., metal). As such, the susceptor 150 and the cover 140 may be electrically connected to each other when the susceptor 150 and the cover 140 are in contact. The susceptor 150 may include a heater 151 for heating the wafer 190 while a process is performed. The wafer 190 may be heated by the heater 151 to a desired temperature necessary for the formation process.

The susceptor 150 may be raised or lowered within a desired range by a drive unit 152 installed (or positioned) below the susceptor 150. For example, when the wafer 190 is loaded, the susceptor 150 may be lowered by a desired distance. When the wafer 190 is unloaded, the susceptor 150 may be raised by a desired distance. The drive unit 152 may be raised and lowered a plurality of lift pins 153 for supporting a lower part of the susceptor 150 to raise and lower the susceptor 150. A wafer supporter 161 may be installed (or positioned) at the center of the susceptor 150 to pass through the susceptor 150. The wafer supporter 161 may be fixed at a center position (or intermediate) of the susceptor 150 rather than raised or lowered concurrently with the susceptor 150. While the susceptor 150 is lowered, the wafer 190 (loaded from the exterior) may be loaded on an upper surface of the wafer supporter 161. When the susceptor 150 is raised, the wafer 190 loaded on the wafer supporter 161 may be supported on the upper surface of the susceptor 150.

A gas inlet port 135 may be formed at one side of the inner chamber 130 to introduce a gas into the inner chamber 130. A gas supply unit 139 may be connected to the gas inlet port 135 to supply a process gas or a cleaning gas into the inner chamber 130. The gas supply unit 139 may include a process gas supply unit 131 and a cleaning gas supply unit 132. The process gas supply unit 131 may supply a process gas into the inner chamber 130 through a gas supply line 133 connecting the process gas supply unit 131 and the gas inlet port 135. The process gas may include a source gas. The source gas may be formed of one reaction gas or several types of reaction gas (e.g., a first reaction gas including a metal source and a second reaction gas for providing oxygen or nitrogen to the metal source) and/or a purge gas provided to deposit a thin layer on the wafer 190. The second reaction may be one selected from the group including oxygen (O₂), nitrogen (N₂), water (H₂O) and ammonia (NH₃). The cleaning gas supply unit 132 may supply a cleaning gas into the inner chamber 130 through a gas supply line 134 connecting the cleaning gas supply unit 132 and the gas inlet port 135. The cleaning gas may be formed of one selected from the group including BClₓ, SiClₓ, SF₆, NF₃, Cl₂, SiBr₄, C₄F₆, C₄F₈, CF₅, CHF₃ and a combination thereof. A gas discharge port 137 may be formed at the other side of the inner chamber 130 to discharge a gas in the inner chamber 130. A gas exhaust unit 136 may be connected to the gas discharge port 137 to discharge the gas in the inner chamber 130. The gas exhaust unit 136 may exhaust the gas in the inner chamber 130 through a gas exhaust line 138 connecting the gas exhaust unit 136 and the gas discharge port 137.

An electrode 170 may be installed in the inner chamber 130. The electrode 170 may be formed of a conductive material (e.g., metal). The electrode 170 may have an elongated shape disposed (or arranged) along a longitudinal direction of the inner chamber 130. The electrode 170 may be disposed (or positioned) at the center of the inner chamber 130 and insulated from the inner chamber 130 such that a process gas or a cleaning gas supplied into the inner chamber 130 moves along the inner surface of the inner chamber 130. Reference numeral 176 denotes an insulating member for insulating the electrode 170 from the inner chamber 130.

An electrode plasma power supply 171 may be connected to the electrode 170 in order to apply power to the electrode 170. The electrode plasma power supply 171 may apply high frequency power to the electrode 170 through a power supply line 175 connecting the electrode plasma power supply 171 and the electrode 170. An adapter 173 may be installed on the power supply line 175. The high frequency power generated from the electrode plasma power supply 171 may be applied to the electrode 170 without any (or minimal) loss due to the adapter 173. Reference numerals 177 and 178 denote insulating members for insulating the power supply line 175 from the chambers 110 and 130.

A chamber plasma power supply 154 may be connected to the susceptor 150 of the inner chamber 130 to apply power to the inner chamber 130. The chamber plasma power supply 154 may apply electric power (e.g., high frequency power) to the inner chamber 130 through a power supply line 160 connecting the chamber plasma power supply 154 and the susceptor 150.

A flexible member 158 may be installed (or positioned) below the susceptor 150 to connect a lower surface of the susceptor 150 and the outer chamber 110. The flexible member 158 may be contracted or expanded by a desired distance depending on the position of the susceptor 150 when the susceptor 150 is raised or lowered. The flexible member 158 may have a tube shape. A connector 159 electrically connected to the susceptor 150 may be interposed between two flexible members 158 or inserted in the flexible member 158. The chamber plasma power supply 154 may apply power to the inner chamber 130 through the connector 159. The chamber plasma power supply 154 may include at least two plasma power supplies 155, 156 for applying power having frequencies different from each other. The plasma power supplies 155, 156 may alternately, or sequentially, apply power to the inner chamber 130 using a central control unit 180 that controls the plasma processing apparatus 100. An adapter 157 may be installed on the power supply line 160. The power generated from the chamber plasma power supply 154 may be applied to the inner chamber 130 without any (or minimal) loss due to operation of the adapter 157.

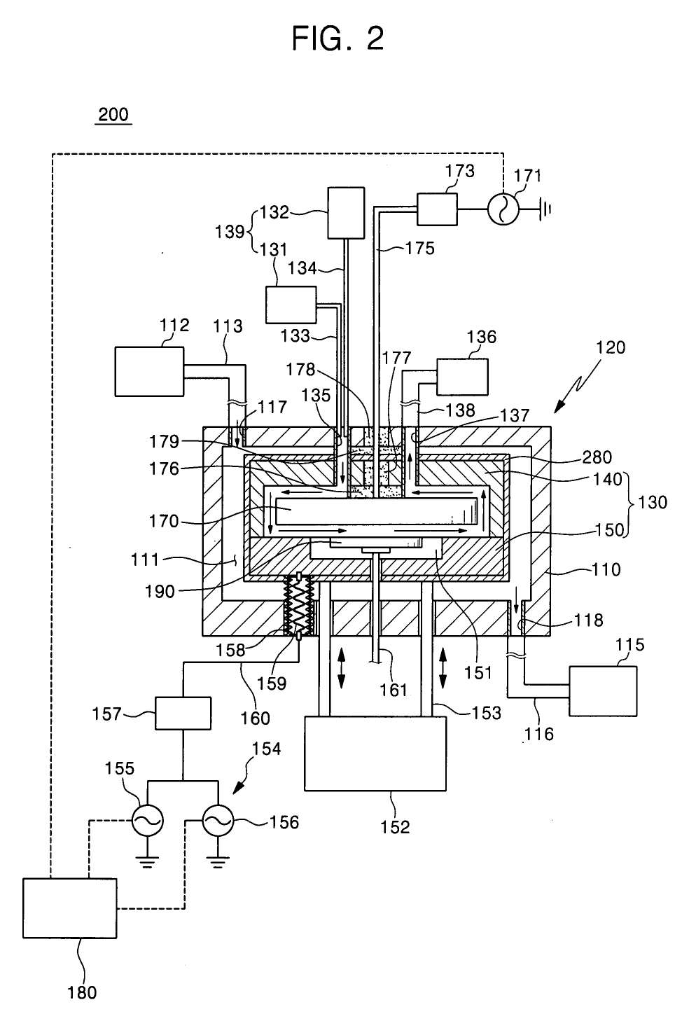

The plasma processing apparatus described above may be implemented in other example embodiments as shown in FIGS. 2 to 4. Because the example embodiments shown in FIGS. 2 to 4 are similar to the plasma processing apparatus shown in FIG. 1, a description of like-elements will be omitted for the sake of brevity.

FIG. 2 is a diagram illustrating a schematic view of a plasma processing apparatus according to example embodiments.

Referring to FIG. 2, the plasma processing apparatus 200 may include an inner chamber 130. A non-conductive material layer 280 may be coated on an outer surface of the inner chamber 130. The non-conductive material layer 280 may be formed of ceramic. Because a substantially weaker electric field is formed between the inner chamber 130 and the outer chamber 110, it may be more difficult to discharge plasma between the inner chamber 130 and the outer chamber 110.

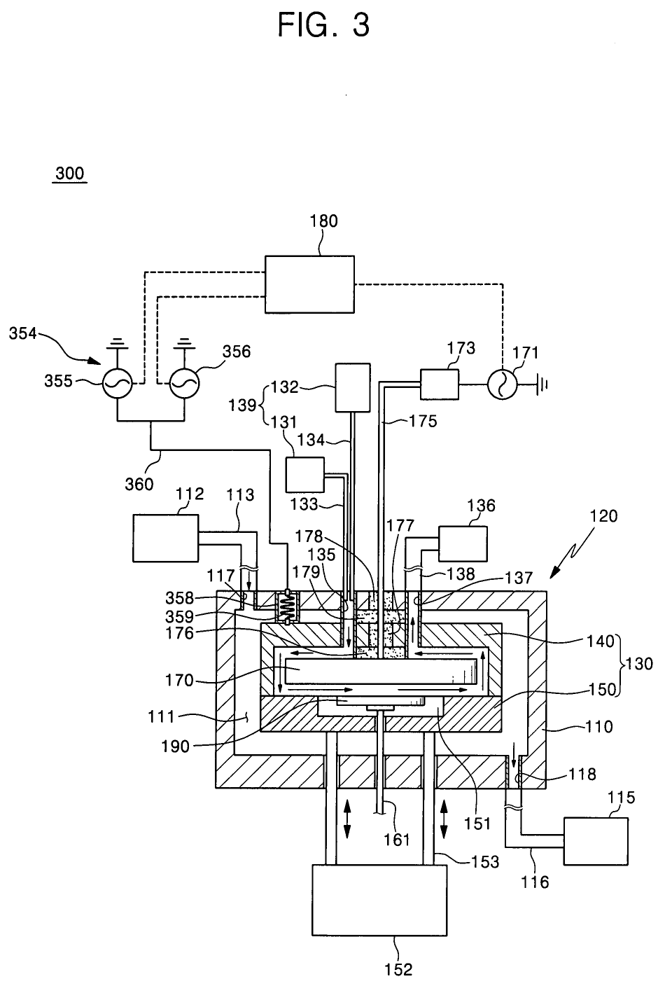

FIG. 3 is a diagram illustrating a schematic view of a plasma processing apparatus according to example embodiments.

Referring to FIG. 3, the plasma processing apparatus 300 may include an inner chamber 130 having a susceptor 150 and a cover 140. A chamber plasma power supply 354 may be connected to the cover 140 of the inner chamber 130 to apply power to the inner chamber 130. The chamber plasma power supply 354 may apply electric power (e.g., high frequency power) to the inner chamber 130 through a power supply line 360 connecting the chamber plasma power supply 354 and the cover 140.

A fixing member 358 may be installed (or positioned) on the cover 140 to connect an upper surface of the cover 140 and the outer chamber 110. The fixing member 358 may have a tube shape. The fixing member 358 may be formed of a flexible material. A connector 359 may be interposed in the fixing member 358 to electrically connect the fixing member 358 to the cover 140. The chamber plasma power supply 354 may apply power to the inner chamber 130 through the connector 359. The chamber plasma power supply 354 may include at least two plasma power supplies 355, 356 to apply power of different frequencies. The plasma power supplies 355, 356 may be connected to a central control unit 180 to alternately, or sequentially, apply power to the inner chamber 130 under the control of the central control unit 180. An adapter (not shown) may be installed (or positioned) on the power supply line 360. The power generated from the chamber plasma power supply 354 may be applied to the inner chamber 130 without any (or minimal) loss due to operation of the adapter.

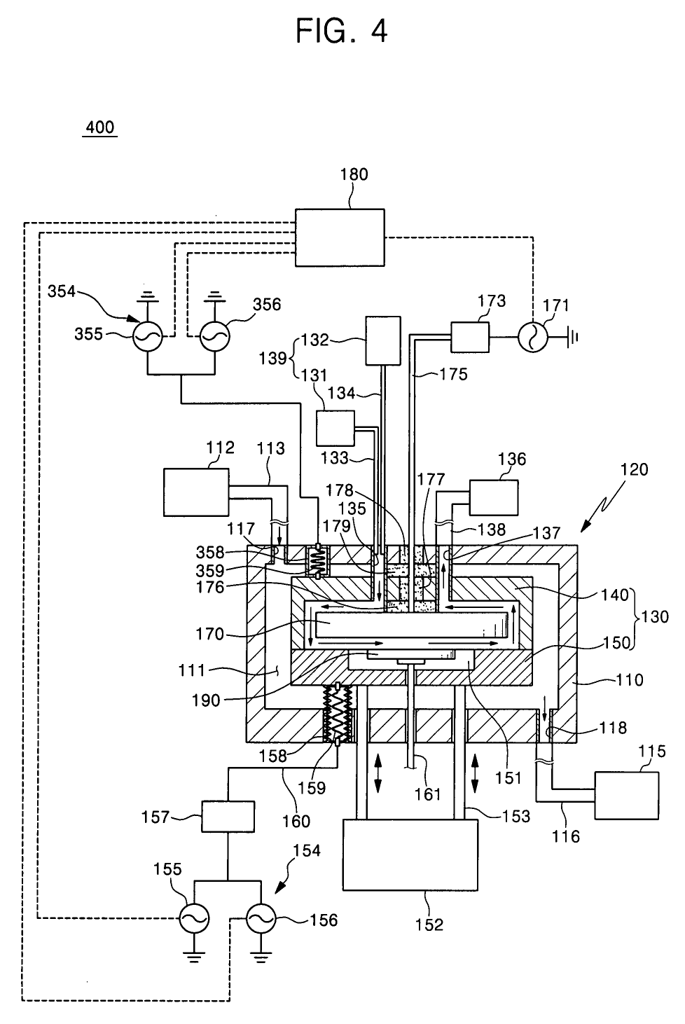

FIG. 4 is a diagram illustrating a schematic view of a plasma processing apparatus according to example embodiments.

Referring to FIG. 4, the plasma processing apparatus 400 may include a chamber plasma power supply 154 connected to a susceptor 150 and/or a chamber plasma power supply 354 connected to a cover 140. The chamber plasma power supplies 154, 354 may include at least two plasma power supplies 155, 156 or 355, 356, respectively, for applying power of different frequencies. The plasma power supplies 155, 156, 355, 356 may be connected to a central control unit 180 in order to alternately, or sequentially, apply power to the inner chamber 130 under the control of the central control unit 180.

A method of using a plasma processing apparatus will now be described. Although a process of forming a thin layer using the plasma processing apparatus will be described using a PEALD method, example embodiments are not limited thereto.

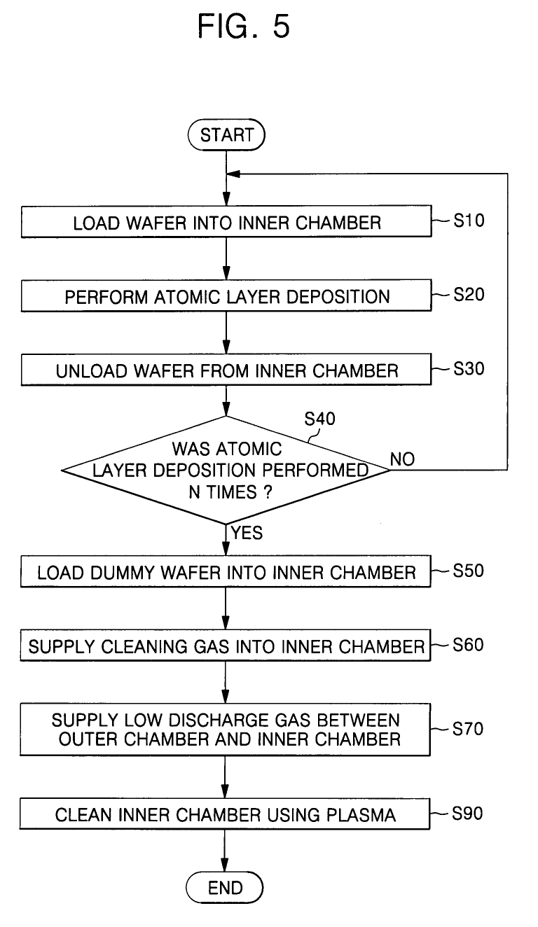

FIG. 5 is a flowchart of a method of using a plasma processing apparatus according to example embodiments.

After loading a wafer 190 (S10), a susceptor 150 of an inner chamber 130 may be lowered a desired distance by a drive unit 152. The susceptor 150 may be separated from a cover 140. The wafer 190 may be transferred to a wafer supporter 161 through a gate (not shown) of an outer chamber 110 by means of a wafer transfer arm (not shown). When the wafer 190 is transferred to the wafer supporter 161, the susceptor 150 may be raised and the wafer 190 may be mounted on the susceptor 150. The susceptor 150 and the cover 140 may contact each other such that a seal that defines a space for performing a process is created (e.g., a hermetically sealed space).

When a gap between the susceptor 150 and the cover 140 is sealed to define the process performing space, a PEALD process may be performed (S20). The PEALD process may be used to deposit various materials (e.g., a compound semiconductor, a silicon oxide layer, a metal oxide layer, a metal nitride layer, etc.). A metal and a nonmetal may be alternately used as a reaction material. According to the PEALD process, because the material may be completely reacted with the metal, it may be possible to form a better metal oxide layer or metal nitride layer. For example, a high-k dielectric layer (e.g., HfO₂, Al₂O₃, ZrO₃, etc.) may be formed by the PEALD process. The dielectric layer may be formed by alternately supplying a first reaction gas including a metal source and a second reaction gas including oxygen and nitrogen through a gas inlet port 135. A purge gas may be supplied between alternately supplying the first reaction gas and the second reaction gas. The purge gas may be continuously supplied while the PEALD process is performed. The purge gas may be Ar, N₂, He or a similar gas. When a process gas including the first reaction gas, the second reaction gas and the purge gas is supplied into the inner chamber 130, a central control unit 180 may select an electrode plasma power supply 171. The selected electrode plasma power supply 171 may apply high frequency power to an electrode 170 in the inner chamber 130 through a power supply line 175. Plasma may be generated from the process gas in the inner chamber 130 by the high frequency power applied to the electrode 170 and ions of the reaction gas in the plasma may be deposited on a surface of the wafer 190 to form a thin layer.

When the PEALD process is complete, the wafer 190 may be unloaded from the inner chamber 130 (S30). An unloading method of the wafer 190 is similar to the loading method of the wafer 190 except the reverse actions are performed.

When the wafer 190 having the thin layer formed thereon is unloaded (S30), a new wafer may be loaded (S10) to perform the PEALD process (S20). As described above, loading the wafer (S10), performing the PEALD process (S20) and unloading the wafer (S30) may be repeatedly performed.

When the PEALD process is performed, a deposited material may remain on an inner surface of the inner chamber 130 and a surface of the wafer 190. The deposited material may function as an impurity on the wafer 190. When a specific number of PEALD processes are performed, it may be necessary to clean the inner chamber 130 because the deposited materials accumulate as the PEALD process is repeated. The number of times the PEALD process is performed (n) may be determined by considering the type or thickness of an atomic layer formed on the wafer 190. Upon determining the number of times the PEALD process was performed (n) (S40), a dummy wafer may be loaded in the inner chamber 130 (S50). Because the deposited material is not formed on a surface of the susceptor 150 on which the wafer 190 may be mounted during the PEALD process, the surface of the susceptor 150 may be protected by the dummy wafer during the following cleaning process.

When the dummy wafer is loaded (S50), an in-situ cleaning process may be performed.

A cleaning gas provided from a cleaning gas supply unit 132 may be supplied into the inner chamber 130 through a gas inlet port 135 (S60). The cleaning gas may be formed of one selected from the group including BClₓ, SiClₓ, SF₆, NF₃, Cl₂, SiBr₄, C₄F₆, C₄F₈, CF₅, CHF₃ and a combination thereof. A low discharge gas having a discharge rate lower than argon gas may be supplied between the inner chamber 130 and an outer chamber 110 surrounding (or enclosing) the exterior of the inner chamber 130 through a gas supply port 117 (S70). The low discharge gas may include O₂ gas, N₂ gas, Ar/O₂ gas and/or Ar/N₂ gas. The low discharge gas may be supplied (S70) concurrently with or before supplying the cleaning gas (S60). Because the low discharge gases are supplied between the inner chamber 130 and the outer chamber 110, minimal (if any) discharge is generated between the inner chamber 130 and the outer chamber 110 even when higher frequency power is applied to the inner chamber 130 and the electrode 170 to clean the inner chamber 30. There may be minimal (if any) loss of the high frequency power because the plasma is generated only in the inner chamber 130 as the higher frequency power is applied.

The central control unit 180 may select an electrode plasma power supply 171 and chamber plasma power supplies 154 or 354 in order that the selected electrode plasma power supply 171 and chamber plasma power supplies 154 or 354, respectively, apply higher frequency power to the inner chamber 130 and the electrode 170 in the inner chamber 130 through the respective power supply lines 175, 160 and 360. When the PEALD process is performed (S20), a higher frequency power may be applied to the inner chamber 130 other than the high frequency power applied to the electrode 170 when the cleaning process is performed because the deposited material is formed on the inner wall surface of the grounded inner chamber 130 to a thickness greater than that of the electrode 170. The magnitude of the high frequency power may be determined by considering the number of times the PEALD processes is performed (n) and the characteristics (e.g., type, thickness, etc.) of the atomic layer. The chamber plasma power supply may be the chamber plasma power supply 154 connected to the susceptor 150. The chamber plasma power supply may be the chamber plasma power supply 354 connected to the cover 140. Because both the cover 140 and the susceptor 150 are formed of a conductive material (e.g., metal), the high frequency power may be transmitted to the inner chamber using the cover 140 or the susceptor 150. When power of different frequencies is individually applied to the electrode 170 and the inner chamber 130, plasma of the cleaning gas may be generated in the inner chamber 130 by the applied high frequency power. The deposited materials formed on the inner wall of the inner chamber 130 may be etched by the plasma of the cleaning gas to be discharged through a gas discharge port 137 simultaneously with the cleaning gas. The interior of the inner chamber 130 may be cleaned (S90).

During the cleaning process, the central control unit 180 may select the chamber plasma power supplies 154, 354 in order that a plurality of plasma power supplies 155, 156, 355, 356 included in the respective chamber plasma power supply 154, 354 may be alternately, or sequentially, selected to apply power of different frequencies. The power of different frequencies may be regularly, or irregularly, applied to the inner chamber 130 in an alternate manner. The characteristics of the plasma of the cleaning gas generated in the inner chamber 130 may vary depending on the alternately applied power, maximizing a cleaning effect of the inner chamber 130.

In accordance with the method of using a plasma processing apparatus, an internal pressure of a flexible member 158 connecting the inner chamber 130 and the outer chamber 110 may be maintained in a state wherein there is no plasma source gas (e.g., a vacuum level) before applying the power to the inner chamber 130 to clean the inner chamber 130 (S90). Even when the high frequency power is applied to the inner chamber 130 and the electrode 170, no plasma may be generated in the flexible member 158, making it possible to protect a connector 159 in the flexible member 158 from the plasma.

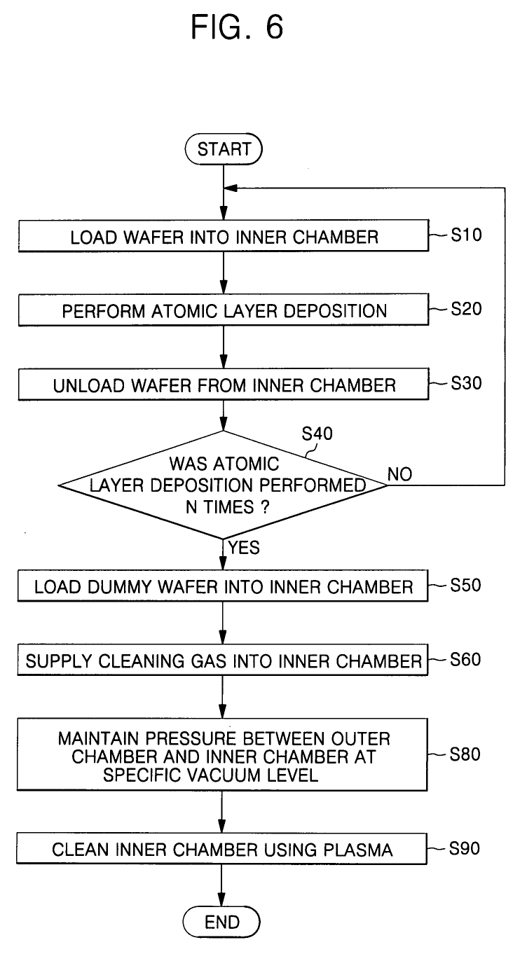

FIG. 6 is a flowchart of a method of using a plasma processing apparatus in accordance with example embodiments. A description of elements similar to those described with reference to FIG. 5 will be omitted for the sake of brevity.

Referring to FIG. 6, a method of using a plasma processing apparatus according to the example embodiments may include maintaining the pressure between the outer chamber 110 and the inner chamber 130 at a desired vacuum level sufficient to suppress generation of plasma (S80) before cleaning the inner chamber 130 using a plasma (S90). In other example embodiments, supplying the low discharge gas (S70) may be omitted to maintain the specific vacuum level. The specific vacuum level may be above 10 Torr or below 10 mTorr. Because the pressure between the inner chamber 130 and the outer chamber 110 may be above 10 Torr or below 10 mTorr (sufficient to suppress plasma generation even when the high frequency power is applied to the inner chamber 130 and the electrode 170 to clean the inner chamber 130), minimal (if any) discharge may be generated between the inner chamber 130 and the outer chamber 110. Because generation of the plasma is restricted to the inner chamber due to the high frequency power, there may be no (or minimal) loss of the high frequency power. Maintaining the pressure between the outer chamber 110 and the inner chamber 130 at a desired vacuum level sufficient to suppress the plasma generation (S80) may be performed simultaneously, or prior to, supplying the cleaning gas (S60).

According to example embodiments described herein, power may be more smoothly applied because the plasma processing apparatus disclosed applies power to an inner chamber using a flexible member connecting the inner chamber and an outer chamber and a connector interposed in the flexible member, even when the inner chamber moves to perform a desired process.

Power having various frequencies may be alternately, or sequentially, applied to the inner chamber to affect the plasma generated in the inner chamber because the plasma processing apparatus in accordance with the example embodiments includes a chamber plasma power supply having at least two plasma power supplies for applying power of different frequencies, maximizing a cleaning effect of the inner chamber.

In accordance with the methods of using a plasma processing apparatus described herein, there may be no (or minimal) plasma generated between the outer chamber and the inner chamber before generating the plasma in the inner chamber to perform a cleaning process because a low discharge gas may be supplied between the outer chamber and the inner chamber. In other example embodiments, a space between the outer chamber and the inner chamber may be maintained at a specific vacuum level sufficient to suppress generation of plasma even when the plasma is generated in the inner chamber. The generated plasma may be restricted to the inner chamber when the high frequency power is applied to the inner chamber, reducing (or eliminating) any loss of the high frequency power. As such, it may be possible to more uniformly maintain a clean state in the inner chamber.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present invention. Accordingly, all such modifications are intended to be included within the scope of this invention as defined in the claims. In the claims, means-plus-function clauses are intended to cover the structures described herein as performing the recited function, and not only structural equivalents but also equivalent structures. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The present invention is defined by the following claims, with equivalents of the claims to be included therein.

What is claimed is:

1. A plasma processing apparatus comprising:
an outer chamber;
an inner chamber installed in the outer chamber;
a gas supply unit for supplying a process gas or a cleaning gas into the inner chamber;
an electrode disposed in the inner chamber;
an electrode plasma power supply for applying power to the electrode;
a first connecting member connecting the inner chamber and the outer chamber, the first connecting member having a first connector therein electrically connected to the inner chamber; and
a first chamber plasma power supply connected to the first connector and applying power to the inner chamber through the first connector.

2. The plasma processing apparatus according to claim 1, wherein the first connecting member is a first flexible member.

3. The plasma processing apparatus according to claim 1, wherein the first chamber plasma power supply includes at least two plasma power supplies for applying power of different frequencies to the inner chamber.

4. The plasma processing apparatus according to claim 1, wherein the inner chamber includes:
a susceptor for mounting a substrate, and
a cover positioned on the susceptor to define a space for performing a process.

5. The plasma processing apparatus according to claim 4, wherein the first connecting member is a first flexible member that connects the susceptor and the outer chamber, and the first chamber plasma power supply applies power to the susceptor through the first connector.

6. The plasma processing apparatus according to claim 1, wherein a non-conductive material layer is coated on an outer surface of the inner chamber.

7. The plasma processing apparatus according to claim 6, wherein the non-conductive material is formed of ceramic.

8. The plasma processing apparatus according to claim 4, wherein the first connecting member is a fixing member connecting the cover and the outer chamber, and
wherein the first connector is electrically connected to the cover.

9. The plasma processing apparatus according to claim 8, wherein the first chamber plasma power supply includes at least two plasma power supplies for applying power of different frequencies to the cover.

10. The plasma processing apparatus according to claim 8, wherein a non-conductive material layer is coated on an outer surface of the inner chamber.

11. The plasma processing apparatus according to claim 10, wherein the non-conductive layer is formed of ceramic.

12. The plasma processing apparatus according to claim 9, further comprising:
a flexible member connecting the susceptor and the outer chamber and having a second connector therein electrically connected to the susceptor; and
a second chamber plasma power supply connected to the second connector, the second chamber plasma power supply applying power to the susceptor through the second connector,
wherein the flexible member is a second connecting member.

13. The plasma processing apparatus according to claim 12, wherein the second chamber plasma power supply includes at least two plasma power supplies for applying power of different frequencies to the susceptor.

14. A method of using a plasma processing apparatus, comprising:
supplying a process gas into an inner chamber installed in an outer chamber to perform a thin-layer forming process on a substrate mounted therein;
supplying a cleaning gas into the inner chamber;
applying at least two powers to the inner chamber and an electrode positioned in the inner chamber and cleaning the inner chamber using plasma generated from the cleaning gas; and
maintaining a pressure between the outer chamber and the inner chamber to suppress generation of the plasma or discharge.

15. The method according to claim 14, wherein maintaining the pressure includes supplying a low discharge gas having a discharge rate lower than argon gas between the outer chamber and the inner chamber.

16. The method according to claim 14, further comprising exchanging the substrate with a dummy wafer before supplying the cleaning gas into the inner chamber and after applying the powers.

17. The method according to claim 15, wherein the low discharge gas is one selected from the group including O₂ gas, N₂ gas and a mixed gas thereof.

18. The method according to claim 14, further comprising connecting a flexible member between the inner chamber and the outer chamber; and forming a connector electrically connected to the inner chamber in the flexible member, before applying the powers to the inner chamber.

19. The method according to claim 18, wherein the power is supplied to the inner chamber through the connector.

20. The method according to claim 19, further comprising maintaining an internal pressure of the flexible member at a vacuum level before applying the powers to the inner chamber.

21. The method according to claim 14, wherein the pressure is maintained at a first vacuum level.

22. The method according to claim 21, further comprising exchanging the substrate with a dummy wafer before supplying the cleaning gas into the inner chamber and after applying the powers.

23. The method according to claim 21, wherein the first vacuum level is above 10 Torr or below 10 mTorr.

24. The method according to claim 21, further comprising:
connecting a flexible member between the inner chamber and the outer chamber; and
forming a connector electrically connected to the inner chamber in the flexible member, before applying the powers to the inner chamber.

25. The method according to claim 24, wherein the powers are supplied to the inner chamber through the connector.

26. The method according to claim 25, further comprising maintaining an internal pressure of the flexible member at a second vacuum level before applying the powers to the inner chamber.
